(19) United States
(12) Patent Application Publication
(10) Pub. No.: US 2010/0244266 A1
(43) Pub. Date: Sep. 30, 2010

(54) METALLIC BONDING STRUCTURE FOR COPPER AND SOLDER

(76) Inventors: Jenq-Gong Duh, Hsinchu City (TW); Chi-Yang Yu, Taoyuan County (TW)

Correspondence Address: Muncy, Geissler, Olds & Lowe, PLLC, 4000 Legato Road, Suite 310, FAIRFAX, VA, 22033, US

(21) Appl. No.: 12/412,929

(22) Filed: Mar. 27, 2009

(51) Int. Cl. H01L 23/488; H05K 1/02

(52) U.S. Cl. 257/762; 257/690; 174/259; 257/E23.069; 257/E23.072

(57) ABSTRACT

The present invention discloses a metallic bonding structure for copper and solder, which applies to connect at least one electronic element. The metallic bonding structure comprises at least one copper-based member and at least one zinc bonding member. The copper-based members are arranged on the electronic element through at least one solder member. The zinc bonding members are arranged between the copper-based members and the solder members. The solder members are tin-based solder bumps.

### FIELD OF THE INVENTION

The present invention relates to a technology for promoting the strength and reliability of electronic elements, particularly to a metallic bonding structure for copper and solder.

### BACKGROUND OF THE INVENTION

The first stage of electronic package is to bond a chip to a carrier board via one of the following three technologies-wire-bonding, TAP (Tape Automatic Bonding), and F/C (Flip Chip).

The wire-bonding process has a bottleneck of consuming a longer time. Further, the electronic component packaged by the wire-bonding or TAB technology has a larger volume, which conflicts the trend of slim and lightweight electronic products. Thus, the F/C technology is developed to reduce the size of electronic products.

The F/C technology can achieve a compact, high-pin-count, better-heat-dissipation electronic package. Further, compared with the wire-bonding technology, the F/C technology can greatly reduce the length of the connection wires and effectively increase the speed of electronic signal transmission. Therefore, F/C has been the mainstream of high-density electronic package.

Refer to FIG. 1 for the structure of a conventional electronic package. A chip 1 has a plurality of solder pads 2, and the substrate 3 has a plurality of contacts 4.A plurality of tin-based solder bumps 5 is arranged between the solder pads 2 and the contacts 4 to bond the chip 1 to the substrate 3. The solder pads 2 and the contacts 4 are made of copper. The electric connection bonds the chip 1, through the solder pads 1, the tin-based solder bumps 5 and the contacts 4 in sequence, to the substrate 3. A resin 6 is filled between the chip 1 and the substrate 3 to prevent from the damages caused by humidity and stress.

Refer to FIG. 2 for an electronic microscope photograph of the soldering junction in a conventional technology. The tin-based solder bumps 5 will rapidly react with the cupric solder pads 2 and contacts 4 to produce a great amount of at least one intermetallic layer 7, such as Cu₆Sn₅ and/or Cu₃Sn, with appearing a plurality of voids 8 simultaneously. The abovementioned phenomenon usually appears after an F/C-packaged component has been tested or used for a period time. When the tin-based solder bumps 5 are melted into a liquid phase, the intermetallic layers 7 begin to appear to vary the surface tension of the melted solder and increase the wettability thereof. The intermetallic layers 7 have a high strength and can increase the strength of the soldering junction. However, the intermetallic material is an ionic-bond compound, which is usually brittle. Further, the thermal expansion coefficients of the intermetallic layers 7 are different from the thermal expansion coefficients of the solder pads 2, the contacts 4 and the tin-based solder bumps 5. Therefore, over amount of intermetallic layer 7 is likely to harm the regions contacting the tin-based solder bumps 5.

Moreover, the formed voids 8 will greatly weaken the bonding capability between the tin-based solder bumps 5 and the solder pads 2/contacts 4. The formation of the voids 8 correlates with the diffusion rates of copper atoms and tin atoms in the intermetallic layer 7 (Cu₃Sn). Because copper atoms diffuse faster than tin atoms, the vacancies in the interface where copper contacts the intermetallic layers 7 are so hard to be well compensated and finally accumulate to form the voids 8. Copper atoms also diffuse along the grain boundaries and then into the lattice of tin to react with tin atoms and form another intermetallic layer 7 (Cu₆Sn₅).

The intermetallic layers 7 and voids 8 occurring in the conventional technology will reduce the mechanical strength of the soldering structure in practical application. Refer to FIG. 3 for the process of thermally damaging the soldering structure. As there are differences of thermal expansion coefficients of the chip 1, the resin 6 and the substrate 3, heat generated in operation will result in thermal stresses, which will affect the mechanical strengths of the chip 1, the resin 6 and the substrate 3. The thermal stresses are likely to concentrate on the interfaces where the tin-based solder bumps 5 contact the chip 1/substrate 3 and cause fatigue, which will finally bring about the cracking of the soldering structure and the malfunction of electronic products.

### SUMMARY OF THE INVENTION

One objective of the present invention is to provide a metallic bonding structure for copper and solder to promote the strength and reliability of the connection of a chip and a substrate.

To achieve the abovementioned objective, the present invention proposes a metallic bonding structure for copper and solder, which applies to connect at least one electronic element. The metallic bonding structure comprises at least one copper-based member and at least one zinc bonding member. The copper-based members are arranged on the electronic element through at least one solder member. The zinc bonding members are arranged between the copper-based members and the solder members.

Based on the abovementioned technical scheme, the present invention has improvements over the conventional technology. The present invention can reduce the intermetallic compounds (such as Cu₆Sn₅ and/or Cu₃Sn) appearing in the interface where the solder members contact the copper-based members and inhibit the formation of voids. The present invention can prevent the copper-based members from being consumed by the generation of the intermetallic compounds. Thus, the present invention can guarantee the mechanical strength and electric conduction of the copper-based members, the zinc bonding members, the solder members and the electronic element.

Therefore, the present invention can promote the yield, quality, and service life of electronic products, and the consumers can benefit therefrom.

### BRIEF DESCRIPTION OF THE DRAWINGS

FIG. 1 is a diagram schematically showing the structure of a conventional electronic package;

FIG. 2 is an electronic microscope photograph of the soldering junction in a conventional technology;

FIG. 3 is a diagram schematically showing the thermally damage of the soldering structure in a conventional electronic package;

FIG. 4 is a diagram schematically showing a metallic bonding structure for copper and solder according to the present invention;

FIG. 5 is a diagram schematically showing a metallic bonding structure for copper and solder according to one embodiment of the present invention;

FIG. 6 is a diagram schematically showing a metallic bonding structure for copper and solder according to another embodiment of the present invention;

FIG. 7 is a diagram schematically showing a metallic bonding structure for copper and solder according to the other embodiment of the present invention;

FIG. 8 is an electronic microscope photograph of the copper-zinc bonding member according to the present invention;

FIG. 9A is a diagram schematically showing that the present invention is applied to an F/C package structure;

FIG. 9B is a first partially enlarged view of FIG. 9A; and

FIG. 9C is a second partially enlarged view of FIG. 9A.

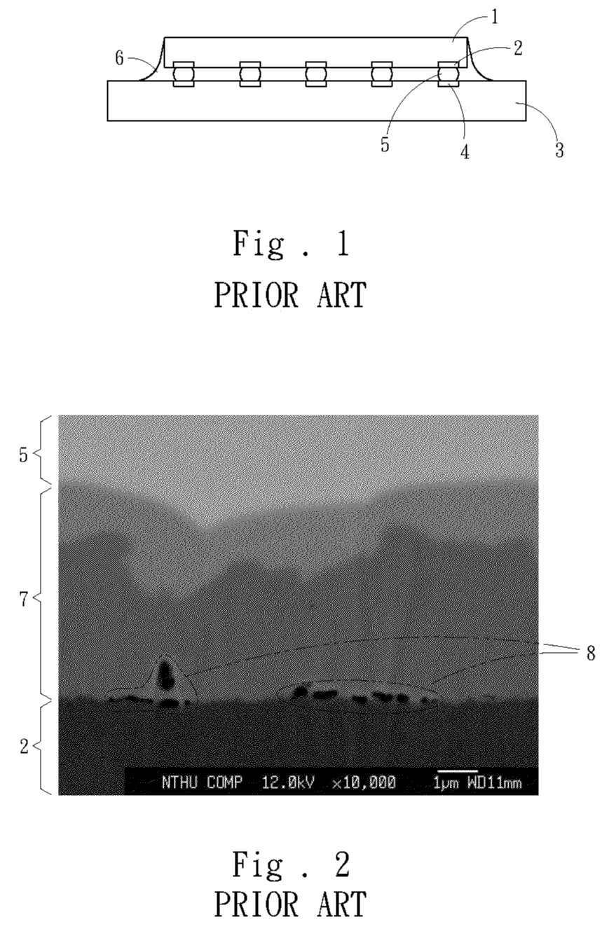

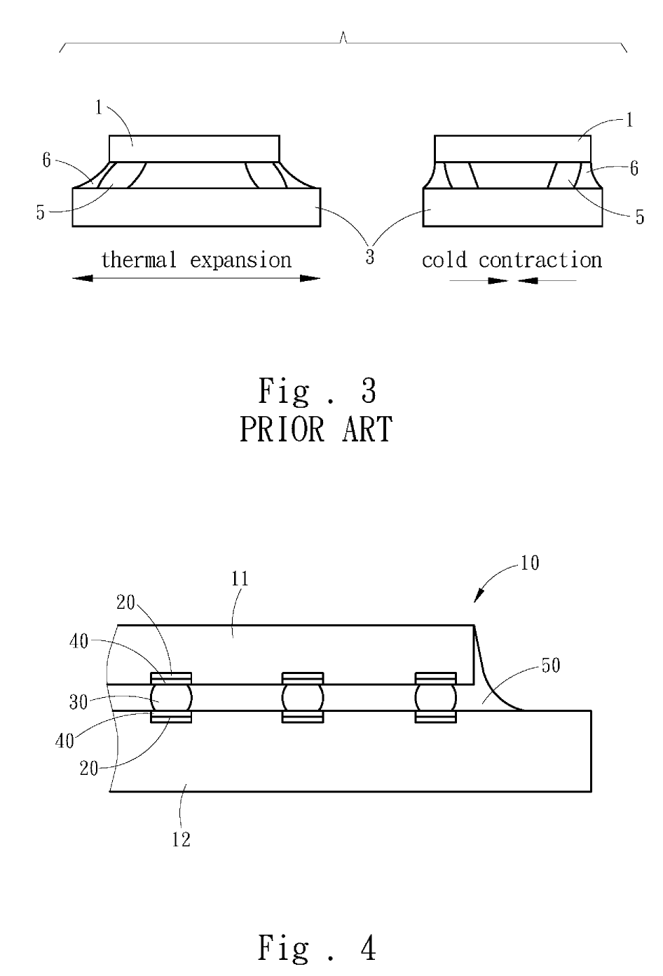

### DETAILED DESCRIPTION OF THE PREFERRED

### Embodiments

Below, the technical contents of the present invention are described in detail with the embodiments. However, it should be understood that the embodiments are only to exemplify the present invention but not to limit the scope of the present invention.

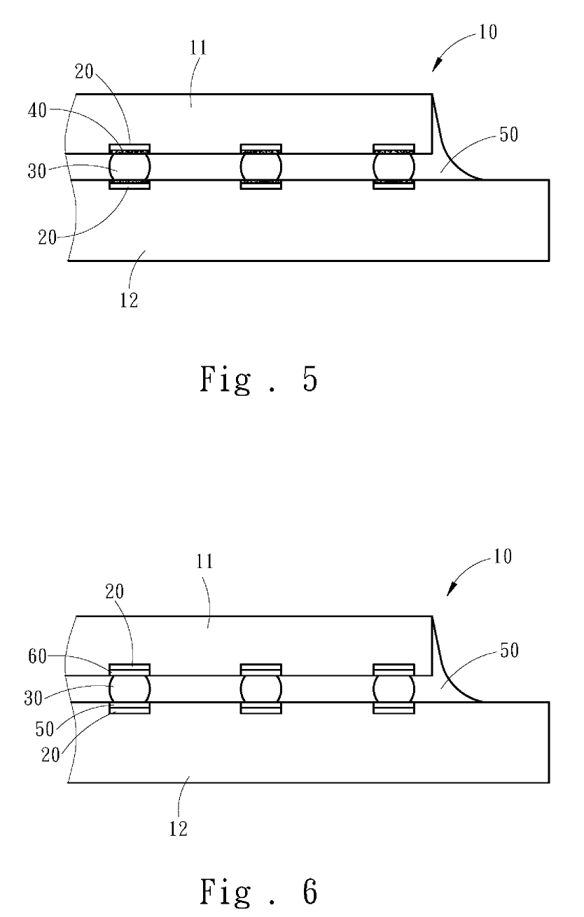

Refer to FIG. 4 a diagram schematically showing a metallic bonding structure for copper and solder according to the present invention. The present invention proposes a metallic bonding structure for copper and solder, which comprises at least one copper-based member 20 and at least one zinc bonding member 40. The copper-based members 20 are arranged on an electronic element 10. At least one solder member 30 is used to solder the electronic element 10, and the zinc bonding members 40 are arranged between the copper-based members 20 and the solder members 30. The solder members 30 are tin-based solder bumps. The electronic element 10 is a chip 11 or a substrate 12. The zinc bonding member 40 is in form of a film, a sheet, a powder, a column, or an alloy. Refer to FIG. 5 for a first embodiment of the present invention. In the first embodiment, the zinc bonding member 40 is in form of a powder, and a resin 50 is filled into between the chip 11 and the substrate 12 for securing the package structure.

Refer to FIG. 4 again, and refer to FIG. 6 for a second embodiment of the present invention. The zinc bonding members 40 combine with copper bonding members (not shown in the drawing) to form copper-zinc bonding members 60 between the copper-based members 20 and the solder members 30. The copper bonding members 20 are made of copper or brass. The zinc bonding members 40 and the copper bonding members are fabricated into the copper-zinc bonding members 60 with an electroplating method, an autocatalytic plating method, a chemical reaction synthesis method, a sputtering method, a rolling method, a fusion method, or a powder synthesis method.

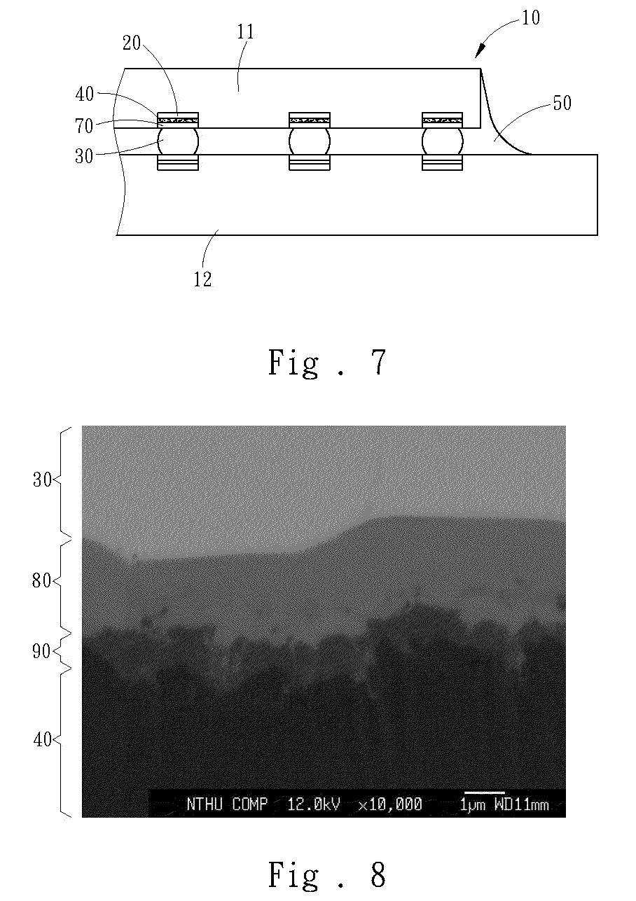

Refer to FIG. 7 for a third embodiment of the present invention. In the third embodiment, at least one wetting layer 70 is arranged between the zinc bonding member 40 and solder member 30. The wetting layer 70 is in form of a metal bump. The zinc bonding member 40 is interposed between the wetting layer 70 and the copper-based member 20.

Refer to FIG. 8 for an electronic microscope photograph of the copper-zinc bonding member according to the present invention. The photograph shows the reaction products in the interface where the solder member 30 contacts the zinc bonding member 40 after the sample is heat-treated at a temperature of 150° C. for 40 days. During the long-time heat treatment, the solder member 30 slowly reacts with zinc bonding member 40 to form at least one intermetallic layer (Cu₆Sn₅) 80 and a zinc-containing phase layer 90. The zinc-containing phase layer 90 is a reaction product of copper and zinc. Contrarily, the conventional voids 8 in FIG. 2 do not appear in FIG. 8.

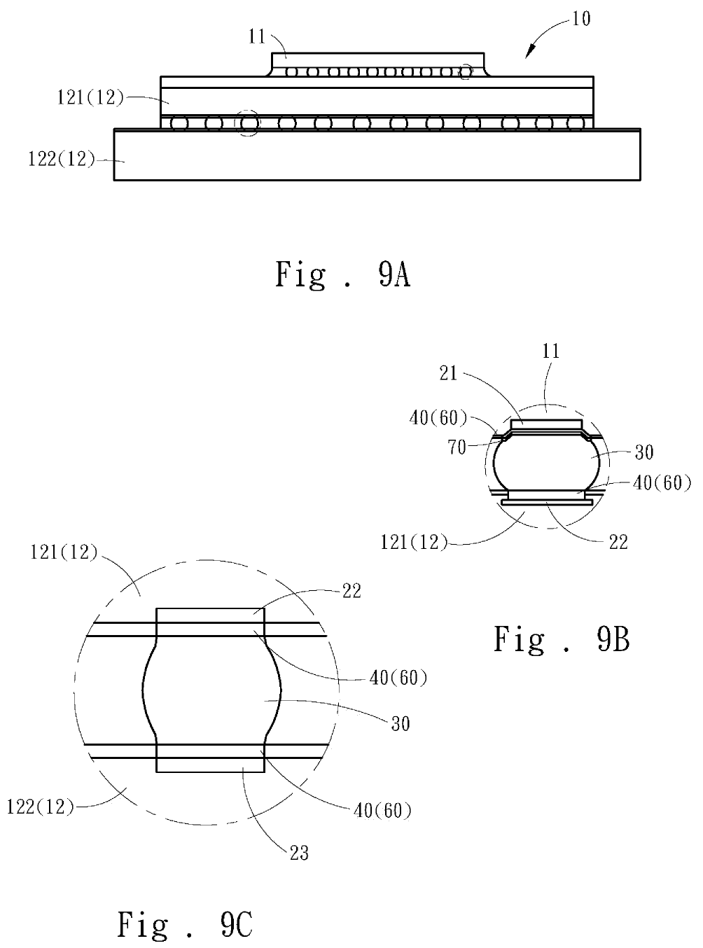

Refer to FIG. 4 again, and refer to FIGS. 9A-9C as well. FIG. 9A is a diagram schematically showing that the present invention is applied to an F/C package structure. FIG. 9B is a first partially enlarged view of FIG. 9A. FIG. 9C is a second partially enlarged view of FIG. 9A. As mentioned above, the electronic element 10 in FIG. 4 may be the chip 11 or the substrate 12. The copper-based members 20 on the substrate 12 may be the copper wires (not shown in the drawing) of the substrate 12. The copper-based members 20 on the chip 11 may be the copper wires 21 (shown in FIG. 9B) of the chip 11. In FIG. 9B, the zinc bonding member 40 (or the copper-zinc bonding member 60) and the wetting layer 70 are arranged between the copper wire 21 and the solder member 30, and the zinc bonding member 40 is arranged between the zinc bonding member 40 and the wetting layer 70. The wetting layer 70 can increase the connection capability and may be in form of a metal bump.

In FIG. 4, FIG. 9A and FIG. 9B, when the electronic element 10 is the substrate 12, the copper-based members 20 may be solder pads where the solder members 30 are arranged. When the substrate 12 is at least one BGA (Ball Grid Array) substrate 121, the BGA substrate 121 has a plurality of BGA solder pads 22, and the solder members 30 are interposed between the BGA solder pads 22 and the wetting layers 70.

In FIG. 4, FIG. 9A and FIG. 9C, when the substrate 12 is a PCB (Printed Circuit Board) substrate 122, the PCB substrate 122 has a plurality of PCB solder pads 23. Thus, the zinc bonding members 40 are interposed between the BGA solder pads 22 and the solder members 30 or between the PCB solder pads 23 and the solder members 30.

In the conventional F/C package technology, the resin 50 is used to prevent from the damage caused by external force. However, the different thermal expansion coefficients of different materials result in thermal stresses. The thermal stresses are likely to concentrate on the interface between the copper-based members 20 and the solder members 30 and then cause the fatigue of materials. Finally, the mechanical and electric connection is damaged. The superiority of the present invention is to reduce the formation rate of the intermetallic layers 7 shown in FIG. 2, protect the copper-base members from being consumed, and inhibit the formation of voids. Thus, the present invention can greatly promote the mechanical properties and reliability of electronic elements.

In addition to the F/C technology, the present invention can also apply to other package technology including SMT (surface mount technology), the wire-bonding technology, the TAB (Tape Automatic Bonding) technology, the 3D multi-layer chip, etc. The present invention utilizes the zinc bonding members 40 to lower the formation rate of the brittle intermetallic layers 7 (such as Cu₆Sn₅ and/or Cu₃Sn) and inhibit the formation of voids 8. The zinc bonding members 40 makes the zinc-containing phase form in the interface between the copper-based members 20 and the solder members 30, i.e. the zinc-containing phase layer 90 in FIG. 8, which can decrease the diffusion rate of copper atoms and prevent copper atoms from being exhausted. Therefore, the present invention not only can guarantee the mechanical strength of the electronic element 10, the copper-based members 20, the zinc bonding members 40 and the solder members 30 but also can maintain the electric conduction among different materials.

The present invention can promote the yield, quality and mechanical strength of electronic elements and reduce the damage caused by drop. Further, the present invention can make electronic products less likely to have a circuit disconnection and thus can prolong the service life thereof. Therefore, the present invention can increase the willingness to buy the electronic products and benefit the sales thereof.

What is claimed is:

1. A metallic bonding structure for copper and solder, which applies to connect at least one electronic element, comprising:
at least one copper-based member arranged on said electronic element, wherein at least one solder member is used to solder said electronic element; and
at least one zinc bonding member arranged between said copper-based member and said solder member.

2. The metallic bonding structure for copper and solder according to claim 1, wherein zinc bonding member is in form of a film, a sheet, a powder, a column, or an alloy.

3. The metallic bonding structure for copper and solder according to claim 1, wherein said zinc bonding member is fabricated with an electroplating method, an autocatalytic plating method, a chemical reaction synthesis method, a sputtering method, a rolling method, a fusion method, or a powder synthesis method.

4. The metallic bonding structure for copper and solder according to claim 1, wherein said copper-based member is made of copper or brass.

5. The metallic bonding structure for copper and solder according to claim 1, wherein said electronic element is a chip, and said copper-based member is a copper wire on said chip.

6. The metallic bonding structure for copper and solder according to claim 1, wherein at least one wetting layer is arranged between said zinc bonding member and said solder member;
said wetting layer is in form of a metal bump.

7. The metallic bonding structure for copper and solder according to claim 1, wherein said electronic element is a substrate, and said copper-based member is a solder pad where said solder member is arranged.

8. The metallic bonding structure for copper and solder according to claim 7, wherein said substrate is at least one BGA (Ball Grid Array) substrate, and said BGA substrate has a plurality of BGA solder pads.

9. The metallic bonding structure for copper and solder according to claim 7, wherein said substrate is a PCB (Printed Circuit Board) substrate, and said PCB substrate has a plurality of PCB solder pads.

10. The metallic bonding structure for copper and solder according to claim 1, wherein said electronic element is a substrate, and said copper-based member is a copper wire on said substrate.

11. The metallic bonding structure for copper and solder according to claim 1, wherein said solder member is a tin-based solder bump.
